(19) United States
(12) Patent Application Publication
(10) Pub. No.: US 2022/0246661 A1
(43) Pub. Date: Aug. 4, 2022

(54) PHOTOELECTRIC CONVERSION APPARATUS, PHOTOELECTRIC CONVERSION SYSTEM, AND MOBILE BODY

(71) Applicant: CANON KABUSHIKI KAISHA, Tokyo (JP)

(72) Inventors: Tetsuya Itano, Kanagawa (JP); Masahiro Kobayashi, Tokyo (JP); Kohichi Nakamura, Kanagawa (JP); Atsushi Furubayashi, Kanagawa (JP)

(21) Appl. No.: 17/590,672

(22) Filed: Feb. 1, 2022

(30) Foreign Application Priority Data
Feb. 4, 2021 (JP) 2021-016454

(51) Int. Cl. H01L 27/146; H01L 31/024; G06N 20/00

(52) U.S. Cl. CPC H01L 27/14634; H01L 27/14636; H01L 27/14603; G06N 20/00; H01L 31/024

(57) ABSTRACT

A photoelectric conversion apparatus includes a first substrate having a pixel area, a second substrate disposed in a multilayer structure on the first substrate, and a heat dissipation structure. The second substrate includes a processing unit configured to execute a machine learning process on an image signal output from the pixel area. The heat dissipation structure is disposed in a region adjacent to or in a region overlapping the processing unit when seen in a plan view, the processing unit. The heat dissipation structure is formed on the first or second substrate by a semiconductor active region, polysilicon, a structure including a metal connection part, a TSV structure, or a cavity structure, or the heat dissipation structure is attached to the first substrate in an area other than the pixel area. When the structure is formed on the first substrate, it is electrically connected to the second substrate.

### BACKGROUND

### Field of the Disclosure

The present disclosure relates to a photoelectric conversion apparatus, a photoelectric conversion system, and a mobile body using the photoelectric conversion system.

### Description of the Related Art

Japanese Patent Laid-Open No. 2020-072410 describes a manner of disposing elements in a photoelectric conversion apparatus including a machine learning processing unit for performing advanced processing within a chip. In this technique, an electromagnetic shield is provided between a substrate on which a pixel array unit is disposed and a substrate on which the machine learning processing unit is disposed to prevent noise generated in the machine learning processing unit from entering the pixel array unit thereby suppressing degradation in the image quality.

When the machine learning processing unit processes a large amount of data at a high speed in the machine learning processing, heat is generated during the operation, which may cause a problem. However, Japanese Patent Laid-Open No. 2020-072410 does not include a description about heat generation in the machine learning processing unit, although heat generated in the machine learning processing unit is transferred to the pixel array unit, which may cause a problem. In addition, the heat can cause the temperature of the machine learning processing unit itself to rise.

### SUMMARY

In an aspect, the present disclosure provides a photoelectric conversion apparatus including a first substrate having a pixel area in which a plurality of pixels are arranged, a second substrate disposed in a multilayer structure on the first substrate, and a heat dissipation structure, the second substrate including a processing unit configured to execute a machine learning process on an image signal output from the pixel area, the heat dissipation structure being disposed in a region adjacent to or in a region overlapping the processing unit when seen in a plan view, the processing unit, the heat dissipation structure including one of following structures: a structure formed on the second substrate, the structure being a semiconductor active region, polysilicon, a structure including a metal connection part, a TSV structure, or a cavity structure; or a structure formed on the first substrate and electrically connected to the second substrate, the structure being a semiconductor active region, polysilicon, a structure including a metal connection part, a TSV structure, a cavity structure, or a heat dissipation structure attached to an area other than the pixel area.

In another aspect, the present disclosure provides a photoelectric conversion apparatus including a first substrate having a pixel area in which a plurality of pixels are arranged, a second substrate disposed in a multilayer structure on the first substrate, and a heat dissipation structure, the second substrate having a third plane and a fourth plane opposing the third plane, the third plane being bonded to the first substrate, the heat dissipation structure including a TSV structure or a cavity structure exposed on a surface of the photoelectric conversion apparatus on a side of the fourth plane.

In still another aspect, the present disclosure provides a photoelectric conversion apparatus including a first substrate, a second substrate disposed in a multilayer structure on the first substrate, and a third substrate bonded to the second substrate, the first substrate having a pixel area in which a plurality of pixels are arranged, the third substrate being a heat dissipation structure using a MEMS structure.

In still another aspect, the present disclosure provides a semiconductor substrate having a pixel area in which a plurality of pixels are arranged, the semiconductor substrate including a processing unit configured to execute a machine learning process on an image signal output from the pixel area, and a heat dissipation structure, the heat dissipation structure including a structure disposed in a region adjacent to or in a region overlapping the processing unit when seen in a plan view, the structure being a semiconductor active region, polysilicon, a structure including a metal connection part, a TSV structure, or a cavity structure.

Further features of the present invention will become apparent from the following description of exemplary embodiments with reference to the attached drawings.

### BRIEF DESCRIPTION OF THE DRAWINGS

FIGS. 1A, 1B, and 1C each are a schematic diagram illustrating a photoelectric conversion apparatus according to a first embodiment.

FIG. 2 is a schematic diagram illustrating a photoelectric conversion apparatus according to the first embodiment.

FIG. 3 is a schematic cross-sectional view of the photoelectric conversion apparatus according to the first embodiment.

FIG. 4 is a schematic cross-sectional view of the photoelectric conversion apparatus according to the first embodiment.

FIG. 5 is a schematic cross-sectional view of the photoelectric conversion apparatus according to the first embodiment.

FIG. 6 is a schematic cross-sectional view of the photoelectric conversion apparatus according to the first embodiment.

FIG. 7 is a schematic cross-sectional view of the photoelectric conversion apparatus according to the first embodiment.

FIG. 8 is a schematic cross-sectional view of the photoelectric conversion apparatus according to the first embodiment.

FIGS. 9A and 9B are each a plan view of the photoelectric conversion apparatus according to the first embodiment.

FIGS. 10A and 10B are each a plan view of the photoelectric conversion apparatus according to a second embodiment or a third embodiment.

FIG. 11 is a diagram showing an overall configuration of a photoelectric conversion apparatus according to the second embodiment or the third embodiment.

FIG. 12 is a functional block diagram of a photoelectric conversion system according to a fourth embodiment.

FIG. 13 is a functional block diagram of a distance sensor according to a fifth embodiment.

FIG. 14 is a functional block diagram of an endoscopic surgery system according to a sixth embodiment.

FIG. 15A is a diagram illustrating a photoelectric conversion system according to a seventh embodiment, and FIG. 15B is a diagram illustrating a mobile body according to the seventh embodiment.

FIGS. 16A and 16B are each a schematic view of smart glasses according to an eighth embodiment.

FIG. 17 is a schematic view of a diagnosis support system according to a ninth embodiment.

### DESCRIPTION OF THE EMBODIMENTS

Photoelectric conversion apparatuses according to various embodiments of the present disclosure are described below with reference to drawings.

In each of the embodiments described below, an imaging apparatus is mainly described as an example of a photoelectric conversion apparatus to which the present disclosure is applicable, but the application of each embodiment is not limited to the imaging apparatus. For example, each embodiment can be applied to other apparatuses such as a distance measurement apparatus (an apparatus for measuring a distance using a focus detection, TOF (Time Of Flight), or the like), a photometric apparatus (an apparatus for measuring the amount of incident light, etc.), and so on.

### First Embodiment

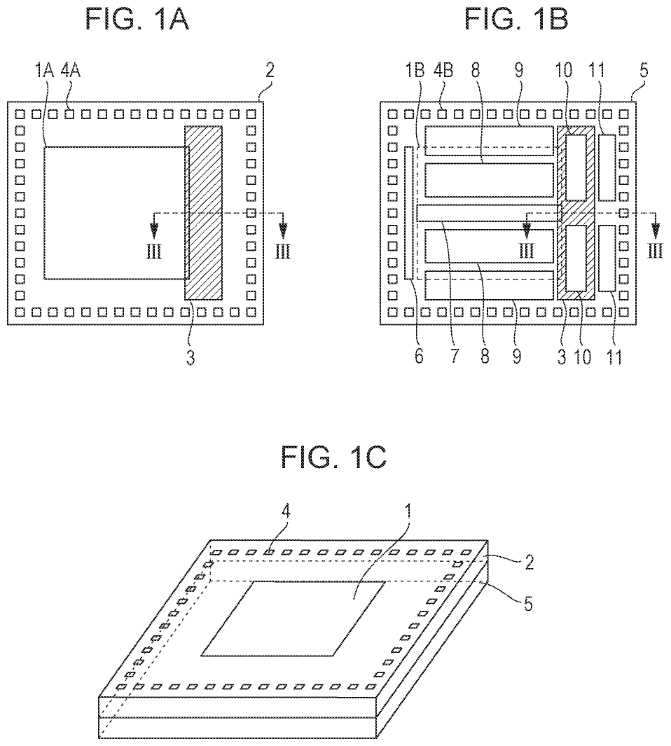

A first embodiment is described below with reference to FIGS. 1 to 9.

FIGS. 1A to 1C each illustrate a photoelectric conversion apparatus according to the first embodiment. More specifically, FIG. 1C is a perspective view of the photoelectric conversion apparatus, and FIGS. 1A and 1B are each a plan view of the photoelectric conversion apparatus in FIG. 1C as viewed from a light incidence side.

As shown in FIG. 1C, the photoelectric conversion apparatus according to the present embodiment has a multilayer structure in which a first substrate 2 and a second substrate 5 are bonded together, and a pixel part 1 and a pad part 4 are provided. A wiring structure is disposed between the first substrate 2 and the second substrate 5. The wiring structure includes a plurality of wiring layers. In the following descriptions, A or B may be used as a subscript of an element name. When an element name has a subscript of A, the element is an element disposed on the first substrate 2, while when an element name has a subscript of B, the element is an element disposed on the second substrate 5. When the first substrate 2 and the second substrate 5 are bonded together, elements A and B are placed so as to overlap each other. Elements with subscripts of A and B are electrically connected to each other via a wiring layer. Alternatively, one the elements A and B may be an opening, and a wiring connected to other one of the elements A and B may be provided so as to passing through the opening until reaching the surface of the substrate. In the photoelectric conversion apparatus shown in FIG. 1C, a surface of the first surface is denoted as a first surface of the first substrate 2, and a surface of the second substrate 5 is denoted as a second surface opposing the first surface.

As shown in FIG. 1A, the first substrate 2 includes a pixel part IA, a heat dissipation part 3, and a pad part 4A disposed in a peripheral area of the first substrate 2.

As shown in FIG. 1B, the second substrate 5 includes a pixel part 1B, a heat dissipation part 3, a pad part 4B, a vertical scanning unit 6, a connection part 7, AD conversion units 8, signal processing units 9, machine learning processing units 10, and output interface units 11. In FIG. 1B, there are two systems each of which includes one AD conversion unit 8, one signal processing unit 9, one machine learning processing unit 10, and one output interface unit 11, disposed such that one system is located in an upper area of the second substrate 5 and the other one system is located in a lower area. In FIG. 1B, the AD conversion unit 8 is connected to the signal processing unit 9, the machine learning processing unit 10, and the output interface unit 11 at one location, but the connection may be made at a plurality of locations.

In FIG. 1B, the machine learning processing unit 10 is divided into two parts, but it does not necessarily need to be divided. Alternatively, functions of the machine learning processing unit 10 as a whole may be achieved by a plurality of physical pieces disposed separately.

The heat dissipation part 3 is formed at least in a part of a region adjacent to the machine learning processing units 10. The region adjacent to the machine learning processing units 10 is, for example, a region which is in contact with the machine learning processing units 10 (including a region between the two divided machine learning processing units 10). Of the regions, electrically connected to the second substrate 5, of the first substrate 2, regions adjacent in a plane to the machine learning processing unit 10 of the second substrate 5, regions or semiconductor active regions adjacent as seen in a plan view (as projected from the upper surface) to the machine learning processing unit are also classified as regions adjacent to the machine learning processing unit 10.

A plurality of pad parts 4 are provided at least in one of the pad part 4A and the pad part 4B, and each pad part 4 includes an input pad and an output pad for outputting or receiving a signal to/from an external circuit. The pad part 4 includes an electrode pad disposed on a wiring layer and electrically connected an external circuit or an electrode pad connected to a through electrode penetrating from one surface of the semiconductor substrate to the opposite surface of the semiconductor substrate. In FIG. 1A and FIG. 1B, four pad parts 4 are disposed in four side areas in the peripheral of the substrate, but the manner of providing the pad parts 4 is not limited to this example, and the pad parts 4 may be provided in another manner.

A connection part 7 is a metal bonding part or a TSV (Through-Silicon Via) structure for electrically connecting the first substrate 2 and the second substrate 5.

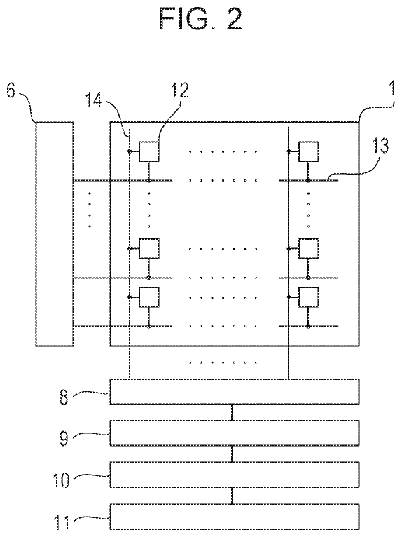

FIG. 2 is a diagram showing an overall configuration of the photoelectric conversion apparatus according to the first embodiment. As shown in FIG. 2, the photoelectric conversion apparatus includes a pixel part 1, a vertical scanning unit 6, an AD conversion unit 8, a signal processing unit 9, a machine learning processing unit 10, and an output interface unit 11. Note that as for elements included in two systems shown in the upper and lower parts in FIG. 1B, only elements in one system are shown in FIG. 2. Also note that the connection part 7 is not shown in FIG. 2.

The pixel part 1 includes a plurality of light receiving pixels 12 arranged in horizontal and vertical directions. Each of the light receiving pixels 12 photoelectrically converts light incident from the outside and generates an electric charge depending on the amount of the incident light. One common pixel drive signal line 13 is provided in each row of the pixel part 1 and pixels in the row are connected to this common pixel drive signal line 13. The light receiving pixels 12 in the pixel part 1 are driven by a control pulse supplied via the pixel drive signal line 13 from the vertical scanning unit 6. One common vertical output line 14 is provided in each column of the pixel part 1, and charges generated by pixels in each column are output as pixel signals via the vertical output line 14. The pixel signals of the light receiving pixels 12 output to the vertical output line 14 in each column is input to the AD conversion unit 8 disposed in each column.

There is no particular restriction on the number of pixels constituting the pixel part 1. For example, in the case of a general digital camera, the pixel part 1 may include pixels arranged in several thousand rows and several thousand columns, or in other applications, the pixel part 1 may include a plurality of pixels arranged in one row or one column.

The AD conversion unit 8 performs the amplification and the AC conversion on the input pixel signal, and supplies the resultant output data to the signal processing unit 9.

The signal processing unit 9 performs signal processing on the output data provided from the AD conversion unit 8. In this signal processing, in addition to the CDS (Correlated Double Sampling), processing corresponding to part of image processing such as an offset removal process may be performed. Furthermore, it is also possible to integrate a part or all of the signal processing unit 9 into the machine learning processing unit 10.

The data output from the signal processing unit 9 is input to the machine learning processing unit 10, and various processes are executed using the trained model created by machine learning.

For example, the trained model is created by machine learning using a deep neural network (DNN). Such a trained model is also called a neural network calculation model.

This trained model may be designed based on parameters which are generated when the input signal corresponding to the output from the pixel part 1 and training data associated with the label of this input signal are input to the particular machine learning model. The particular machine learning model may be a machine learning model using a multilayer neural network. Such a trained model is also called a multilayer neural network model.

The processed data is output via the output interface unit 11.

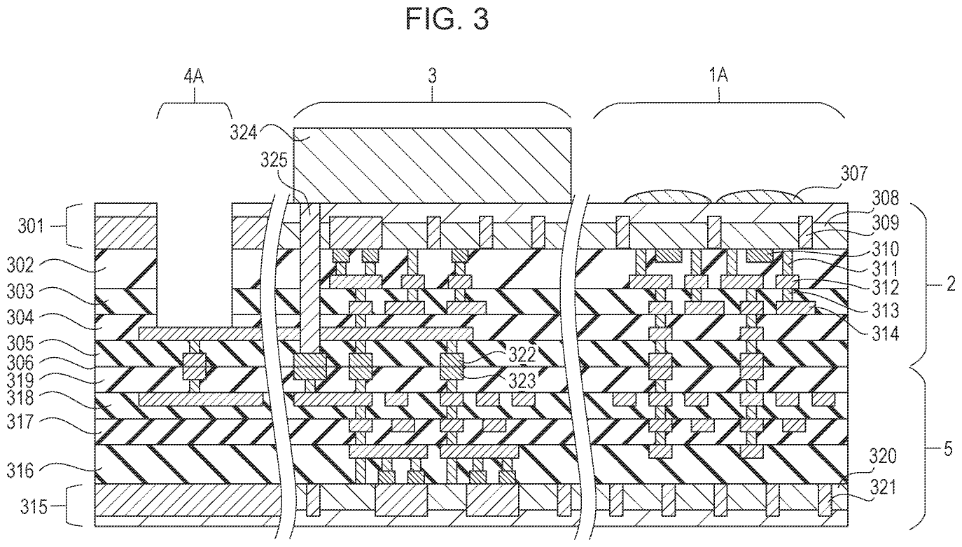

FIG. 3 is a schematic cross-sectional view taken along a line III-III in FIG. 1. More specifically, FIG. 3 illustrates a pixel part IA, a heat dissipation part 3, and a pad part 4A of the first substrate 2, and elements corresponding these elements of second substrate 5. The first substrate 2 and the second substrate 5 each include a multilayer wiring layer structure in which a plurality of wiring layers are disposed via insulating films. The heat dissipation part 3 is provided in a region included in the first substrate 2 and the second substrate 5.

The semiconductor substrate 301 disposed on the light incident side of the first substrate 2 includes element regions 308 isolated by element isolation regions 309.

The interlayer insulating film 302 is made mainly of an insulating material (silicon oxide is used as the insulating material when silicon is used as the semiconductor substrate), and the interlayer insulating film 302 includes a gate electrode layer 310 including a gate electrode and a gate wiring, a wiring layer 312, and a plug layer 311 connecting the element regions 308 and the wiring layer 312.

At a substrate connection plane 306, which is an interface where the first substrate 2 and the second substrate 5 are physically bonded, the first substrate 2 and the second substrate are electrically connected by a metal connection (metal bonding) functioning as a connection part 7.

A plurality of interlayer insulating films 303, 304, and 305 are formed in a multilayer structure between the interlayer insulating film 302 and the substrate connection plane 306. The interlayer insulating film 303 includes a wiring layer 314 and a plug layer 313 connecting wiring layers. The interlayer insulating film 304 also includes a plug layer 313 connecting wiring layers. The interlayer insulating film 305 has a heat dissipation pad 322 for dissipating heat generated by the machine learning processing unit 10 in addition to a wiring layer and a plug layer. The heat dissipation pad 322 can be formed of a conductive pattern formed of the same layer as the wiring layer included in the interlayer insulating film 305.

A semiconductor substrate 315 disposed on the second substrate 5 includes element regions 320. The element regions 320 are isolated by the element isolation regions 321.

An interlayer insulating film 316 includes, as with the interlayer insulating film 302, a gate electrode layer, a wiring layer, and a plug layer. A plurality of interlayer insulating films 317, 318, and 319 are formed in a multilayer structure between the interlayer insulating film 316 and the substrate connection plane 306 at which the first substrate 2 and the second substrate 5 are connected. The interlayer insulating films 317 and 318 each include a wiring layer and a plug layer as with the interlayer insulating films 303 and 304. The interlayer insulating film 319 includes a wiring layer, a plug layer, and a heat dissipation pad 323 as with the interlayer insulating film 305. The heat dissipation pad 323 may be formed, as with the heat dissipation pad 322, of a conductive pattern formed of the same layer as the wiring layer included in the interlayer insulating film 319. The heat dissipation pad 323 and the heat dissipation pad 322 are connected at the substrate connection plane 306.

In each element region 308 in the pixel part IA, transistors, photodiodes, and/or the like constituting a pixel are disposed. A structure that provides capacitance is formed in an element region 308 of the heat dissipation part 3. The element region 308 is also used as a region for supplying a potential of the well. No potential may be applied to the element region 308.

A microlens 307 for collecting light is disposed on the light incident side of the pixel part 1, and a heat dissipation structure 324 is disposed on the light incidence side of the heat dissipation part 3. The heat dissipation structure 324 is, for example, a MEMS (Micro Electro Mechanical Systems) formed by microfabrication technology, and is attached to at least part of a surface of the first substrate 2 in a region other than the pixel area.

Heat generated in the machine learning processing unit 10 is conducted via an element in a region adjacent to the machine learning processing unit 10. For example, in a case where silicon is used as a material of a semiconductor substrate and element isolation regions are realized using silicon oxide, the thermal conductivity of silicon oxide forming each element isolation region is about 1.4 (W/m·K) which is smaller than the thermal conductivity of the element regions (silicon) (about 150 (W/m·K) by two orders of magnitude or more. In view of the above, regions other than the element regions may be formed using silicon, which is the material forming the element regions, instead of using the silicon oxide as the element isolation regions. This makes it possible to increase the regions having high thermal conductivity, which results in enhancing heat dissipation ability. In this case, a PN isolation structure may be used to isolate elements.

The heat generated in the machine learning processing unit 10 is also conducted via polysilicon in a region adjacent to the machine learning processing unit 10. The thermal conductivity of polysilicon is nearly equal to that of silicon, and thus it is possible to increase the number of regions having high thermal conductivity by using polysilicon in forming regions other than the element regions thereby enhancing the heat dissipation ability. In this case, the polysilicon regions may be formed into a mesh-like pattern thereby making it possible to enhance heat dissipation with a higher efficiency.

The heat conducted to the heat dissipation pad 323 through the wiring layer and the plug layer of the second substrate 5 is further conducted to the wiring layer included in the interlayer insulating film 304 through the heat dissipation pad 322 and the plug layer disposed in the interlayer insulating film 305 of the first substrate 2. The wiring layer is connected to the pad part 4A, and heat is dissipated via the pad part 4A. Since the heat is dissipated via parts which electrically connect the first substrate 2 and the second substrate 5 on which the machine learning unit 10 is disposed as described above, it is possible to efficiently dissipate the heat generated in the machine learning unit 10. By using the mesh-like pattern for the wiring layer and the heat dissipation pad that serve as the heat dissipation path, it is possible to achieve the high efficiency heat dissipation.

The heat conducted to the heat dissipation pad 323 through the wiring layer and the plug layer of the second substrate 5 is also dissipated from the surface of the first substrate 2 via the heat dissipation pad 322 disposed in the interlayer insulating film 305 of the first substrate 2 and via the TSV structure 325 formed on the first substrate 2. In this embodiment, since the TSV structure 325 is connected to the heat dissipation structure 324, the heat generated in the machine learning unit 10 can be dissipated with high efficiency via the heat dissipation structure 324. By forming the TSV structure 325 in a mesh-like pattern, it is possible to enhance heat dissipation with a higher efficiency.

More specifically, the TSV structure with a mesh-like pattern may be realized by disposing TSV structures in the form of a matrix, or the TSV structures may be disposed in the form of a matrix and they may be connected to each other via wirings. The mesh pattern is not limited to a two-dimensional mash pattern. For example, TSV structures may be connected vertically and horizontally to form a three-dimensional mesh-like structure.

In FIG. 3, the pad part 4A is configured by way of example such that an opening reaching the interlayer insulating film 304 is formed, and an electrode pad disposed in the opening is electrically connected to the pad part 4B via a wiring layer. However, the structure of the pad part 4 is not limited to this example. For example, the opening may be formed in the pad part 4A so as to reach the interlayer insulating film 318, and the electrode pad may be disposed on the pad part 4B.

### First Modification of First Embodiment

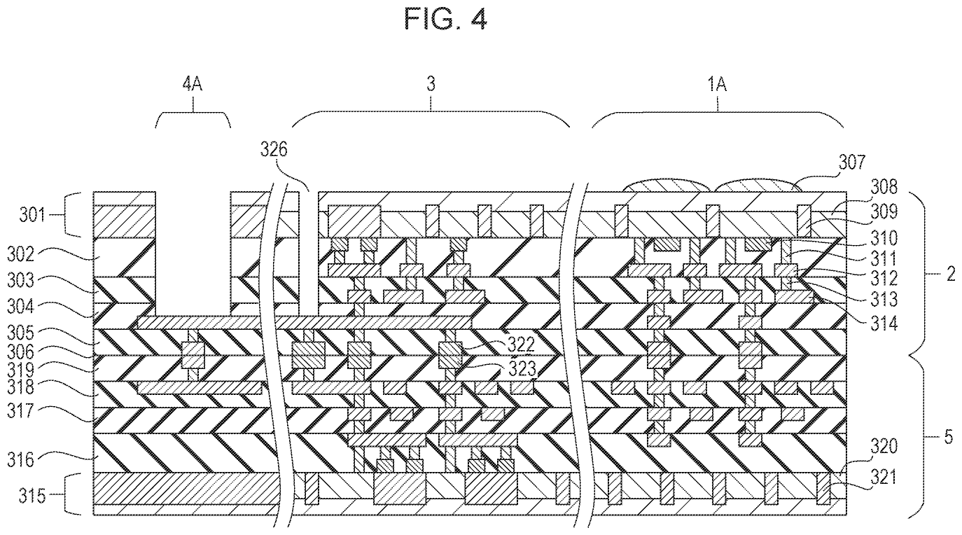

FIG. 4 is a schematic diagram illustrating a photoelectric conversion apparatus according to a modification of the first embodiment. In this configuration, the TSV structure 325 in FIG. 3 is replaced with a cavity structure 326. The cavity structure 326 dissipates heat propagated from the machine learning processing unit 10 as with the TSV structure 325.

The cavity structure 326 is formed in a similar manner to the pad part 4A. In a case where signals are not transmitted to/from an external circuit and thus wire bonding for connecting to the external circuit is not necessary, it is allowed to reduce the size of the cavity. In this case, it is possible to achieve a high heat dissipation ability by forming a plurality of cavity structures thereby achieving an increased contact interface area with the outside of the chip. Furthermore, by forming the cavity structures into a mesh-like pattern, it is possible to achieve further higher dissipation ability.

### Second Modification of First Embodiment

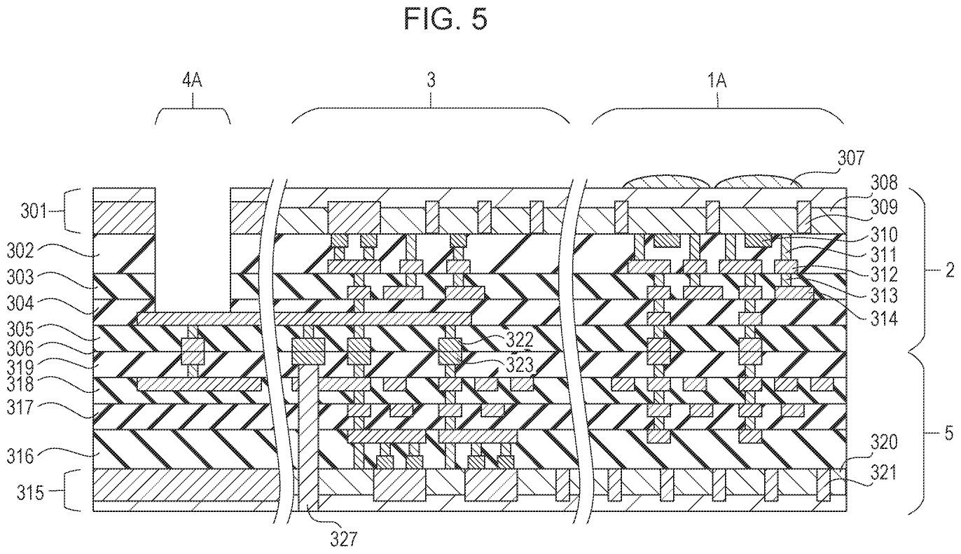

FIG. 5 is a schematic diagram illustrating a photoelectric conversion apparatus according to another modification of the first embodiment. In this modification, unlike the configuration shown in FIG. 3, the TSV structure 325 is not formed in the first substrate 2, but, instead, a TSV structure 327 is formed in the second substrate 5.

The TSV structure 327 is exposed on the surface of the second substrate 5, and heat propagated to the heat dissipation pad 323 via the wiring layer and the plug layer of the second substrate 5 is dissipated from the surface of the second substrate 5 via the TSV structure 327. The surface of the second substrate 5 is in contact with a package, and thus a higher heat dissipation effect can be obtained. In the configuration shown in FIG. 5, it is possible to dissipate heat from a location close to the machine learning processing unit 10 which is a source of heat. This makes it possible to achieve a still higher heat dissipation effect.

### Third Modification of First Embodiment

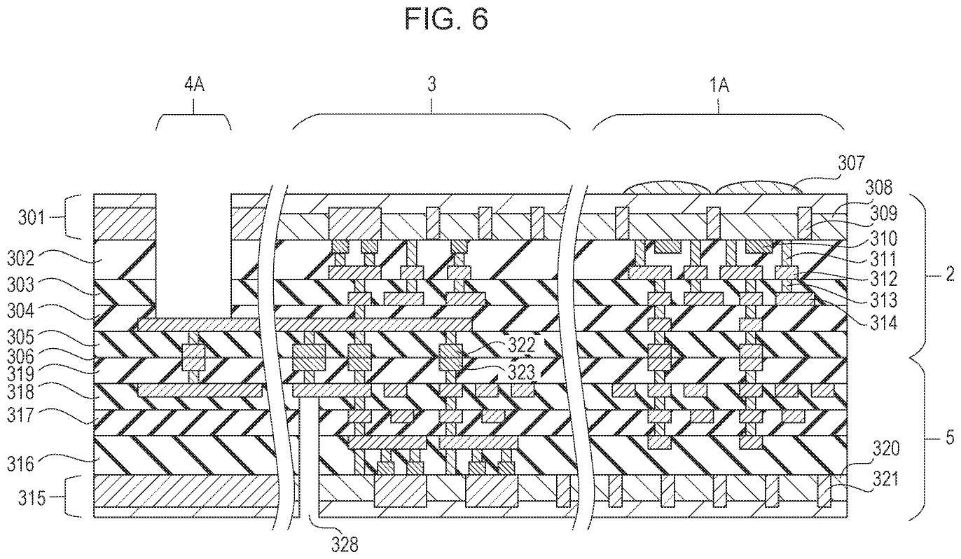

FIG. 6 is a schematic diagram illustrating a photoelectric conversion apparatus according to still another modification of the first embodiment. The TSV structure 327 in FIG. 5 is replaced with a cavity structure 328.

Unlike the cavity structure 326, the cavity structure 328 needs a process to form a heat dissipation structure. Unlike the first substrate 2, the second substrate 5 does not have pixels on its surface, and thus there is less limitation on an area where the cavities 328 are disposed, and many cavity structures can be formed on the second substrate 5. Because of this feature together with the above-described feature that it is possible to dissipate heat from a location close to the machine learning processing unit 10 which is a source of heat, it possible to achieve a still higher heat dissipation effect.

### Fourth Modification of First Embodiment

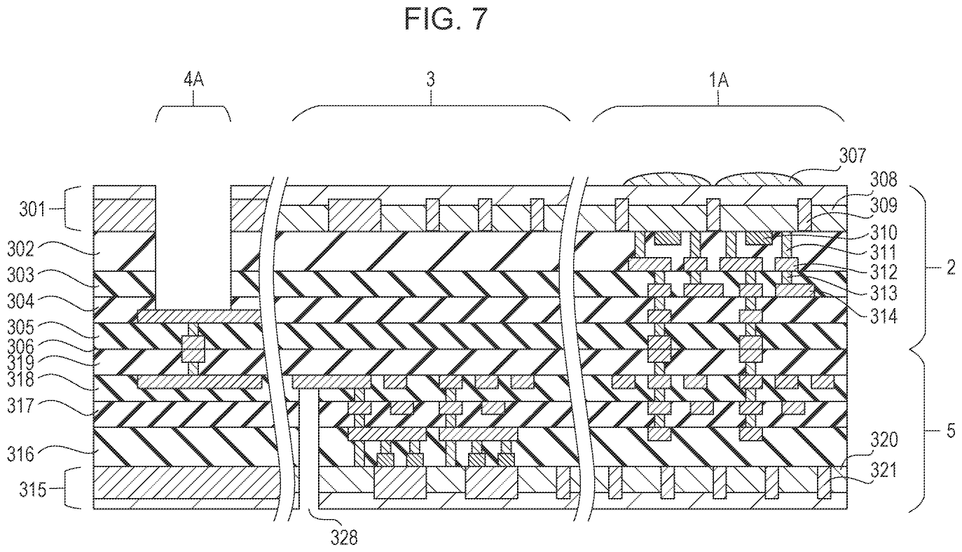

FIG. 7 is a schematic diagram illustrating a photoelectric conversion apparatus according to still another modification of the first embodiment. The heat dissipation pad 323, the heat dissipation pad 322, the wiring layer and the plug layer, of the first substrate 2, connected to the heat dissipation pad 322, and polysilicon, which are provided in the configuration shown in FIG. 6 are not provided in the configuration shown in FIG. 7. That is, the heat dissipation structure does not have a region in contact with the first substrate, and thus heat is dissipated from the surface of the second substrate 5.

Therefore, particularly in a case where the peripheral area of the chip is small and the pixel area occupies a relatively large area of the chip, heat is dissipated via a path which is not close to pixels, and thus the influence of heat on the pixels is suppressed.

### Fifth Modification of First Embodiment

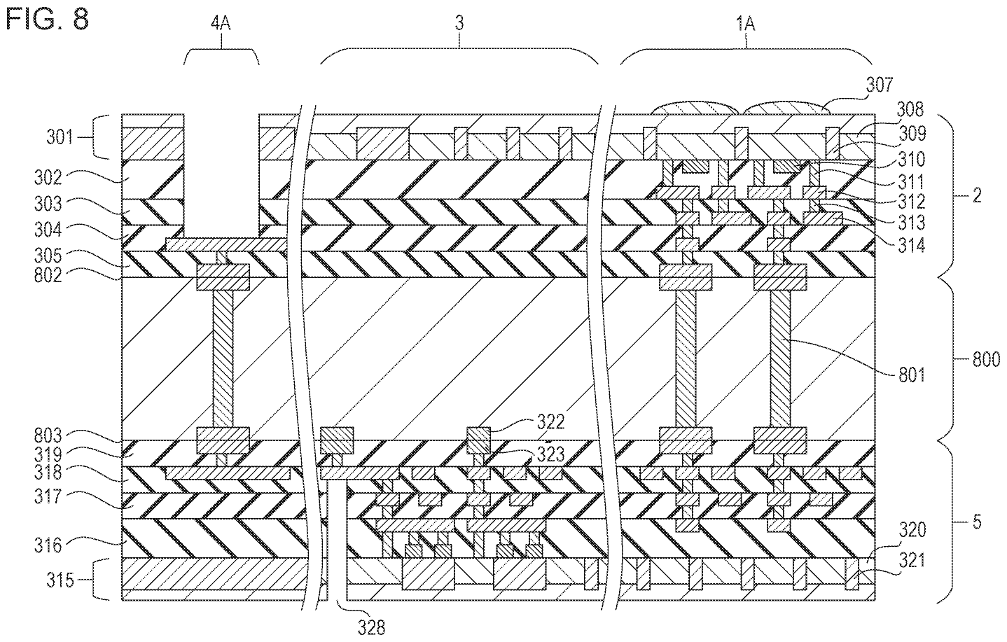

FIG. 8 is a schematic diagram illustrating a photoelectric conversion apparatus according to still another modification of the first embodiment. Unlike the configuration shown in FIG. 7, an additional third substrate 800 is bonded between the first substrate 2 and the second substrate 5.

The first substrate 2 is connected to the third substrate 800 via a substrate connection plane 802, and the second substrate 5 is connected to the third substrate 800 via a substrate connection plane 803, by metal connection parts. Connections between the substrate connection plane 802 and the substrate connection plane part 803 are realized by vias 801. A TSV structure or the like is used for each via 801. The connection between the first substrate 2 and the third substrate 800 and the connection between the second substrate 5 and the third substrate 800 are not shown in FIG. 8. For example, an SRAM or the like is disposed on the third substrate 800.

As the third substrate 800, a heat dissipation structure using a MEMS or the like may be employed. When a heat dissipation structure is used as the third substrate 800, a high heat dissipation effect can be obtained by electrically connecting the second substrate 5 to the third substrate 800 via the heat dissipation pad 323 and the heat dissipation pad 322.

In this modification, as described above, the third substrate 800 is disposed between the first substrate 2 and the second substrate 5. A fourth substrate 804 may be further disposed on a fourth surface of the second substrate 5 opposite to a third surface of the second substrate 5 wherein the third surface of the second substrate 5 refers to a surface connected to the first substrate 2.

### Sixth Modification of First Embodiment

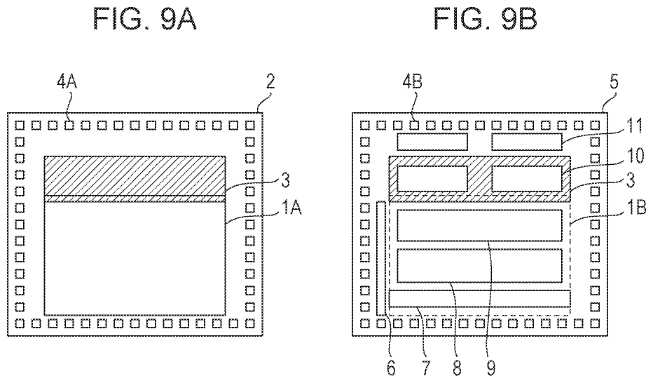

In addition to the manner of disposing the elements of the photoelectric conversion apparatus shown in FIGS. 1A to 1C, it is also possible to dispose the elements in other manners. Another example of a manner of disposing the elements of the photoelectric conversion apparatus is shown in FIGS. 9A and 9B. In the example described above with reference to FIGS. 1A to 1C, two systems each including one AD conversion unit 8 and one signal processing unit 9 are provided such that one is disposed in the upper area and the other is disposed in the lower area. However, in the configuration shown in FIGS. 9A and 9B, only one system is provided.

### Second Embodiment

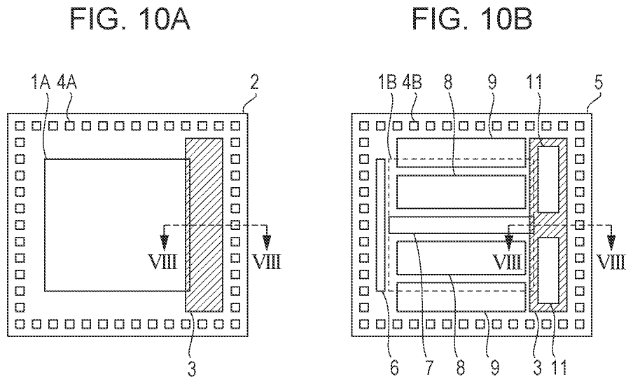

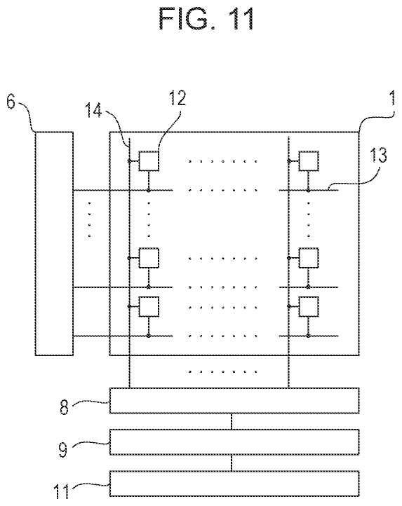

A second embodiment of the present disclosure is described below with reference to FIGS. 10A and 10B and FIG. 11. Detailed descriptions of elements which are similar to those in the first embodiment will be omitted, and the following description will focus on differences from the first embodiment.

FIGS. 10A and 10B each show a photoelectric conversion apparatus according to the second embodiment. A perspective view of the photoelectric conversion apparatus according to the second embodiment is similar to that shown in FIG. 1C. FIGS. 10A and 10B are each a plan view of the photoelectric conversion apparatus as viewed from the light incident side.

As shown in FIG. 10B, the second substrate 5 includes a pixel part 1B, a heat dissipation part 3, a pad part 4B, a vertical scanning unit 6, a connection part 7, an AD conversion unit 8, a signal processing unit 9, and an output interface unit 11.

In the configuration shown in FIG. 10B, two systems each including one AD conversion unit 8, one signal processing unit 9, and one output interface unit 11 are provided such that one is disposed in an upper area and the other is disposed in a lower area. A pad part 4B is disposed in an outer peripheral area of the substrate. In this second embodiment, it is assumed that the output interface unit 11 operates at a high speed, and thus a large amount of heat is generated by the output interface unit 11. Therefore, the heat dissipation part 3 is formed in an area close to the output interface unit 11. However, the heat dissipation part 3 may be formed in another area.

FIG. 11 is a diagram showing an overall configuration of the photoelectric conversion apparatus according to the second embodiment. As shown in FIG. 11, the photoelectric conversion apparatus includes a pixel part 1, a vertical scanning unit 6, an AD conversion unit 8, a signal processing unit 9, and an output interface unit 11. Note that as for elements included in two systems shown in the upper and lower parts in FIG. 1A, only elements in one system are shown in FIG. 2. The connection part 7 is omitted in this figure.

The photoelectric conversion apparatus may further include a machine learning processing unit.

A schematic cross-sectional view taken along a line VIII-VIII in FIG. 10A or 10B is the same as that shown in FIG. 8.

In the present embodiment, a heat dissipation structure is realized by a MEMS structure used as the third substrate 800 bonded between the first substrate 2 and the second substrate 5. A microfluidic structure providing a high heat dissipation effect can be used as the heat dissipation structure. By boding the third substrate 800 with the specially high heat dissipation effect between the first substrate 2 and the second substrate 5, It is possible to suppress the heat propagation to the first substrate 2 from the second substrate 5 on which the output interface unit 11 is disposed.

### Third Embodiment

A third embodiment is described.

The photoelectric conversion apparatus according to the third embodiment is described below also referring to FIGS. 10A and 10B and FIG. 11. Detailed descriptions of elements which are similar to those in the first embodiment or the second embodiment will be omitted, and the following description will focus on differences from the first embodiment.

A schematic cross-sectional view taken along a line VIII-VIII in FIG. 10A or 10B is the same as that shown in FIG. 8.

In the present embodiment, for example, a SRAM is provided as the third substrate 800 bonded between the first substrate 2 and the second substrate 5. The connection between the first substrate 2 and the third substrate 800 and the connection between the second substrate 5 and the third substrate 800 are not shown in FIG. 8. In this configuration, the heat dissipation structure does not have a region in contact with the first substrate and heat is dissipated from the surface of the second substrate 5. Therefore, particularly in a case where the peripheral area of the chip is small and the pixel area occupies a relatively large area of the chip, heat is dissipated via a path which is not close to pixels, and thus the influence of heat on the pixels is suppressed.

In the present embodiment, the third substrate 800 bonded between the first substrate 2 and the second substrate 5 may have a heat dissipation structure realized by a MEMS. By boding the third substrate 800 with the high heat dissipation effect between the first substrate 2 and the second substrate 5 as described above, it is possible to suppress the heat propagation to the first substrate 2 from the second substrate 5 on which the output interface unit 11 is disposed.

### Fourth Embodiment

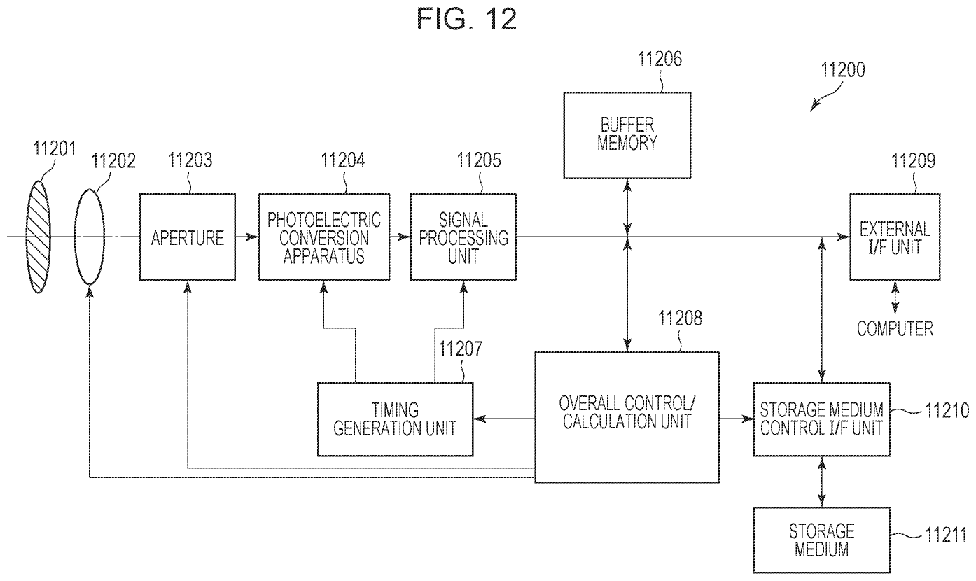

FIG. 12 is a block diagram showing a configuration of a photoelectric conversion system 11200 according to a seventh embodiment. The photoelectric conversion system 11200 according to this embodiment includes a photoelectric conversion apparatus 11204. As for the photoelectric conversion apparatus 11204, the photoelectric conversion apparatus according to one of embodiments described above may be used. The photoelectric conversion system 11200 may be used, for example, as an imaging system. Specific examples of the imaging system include a digital still camera, a digital camcorder, a security camera, a network camera, a microscope, and the like. In the example shown in FIG. 12, the photoelectric conversion system 11200 is used as a digital still camera.

The photoelectric conversion system 11200 shown in FIG. 12 includes a photoelectric conversion apparatus 11204 and a lens 11202 that forms an optical image of a subject on the photoelectric conversion apparatus 11204. The photoelectric conversion system 11200 further includes an aperture 11203 for varying the amount of light passing through the lens 11202, and a barrier 11201 for protecting the lens 11202. The lens 11202 and the aperture 11203 constitute an optical system that focuses light on the photoelectric conversion apparatus 11204.

The photoelectric conversion system 11200 also includes a signal processing unit 11205 that processes an output signal provided from the photoelectric conversion apparatus 11204. The signal processing unit 11205 performs signal processing, such as various correction processing, compression processing unit, on the input signal as necessary, and outputs the resultant signal. The photoelectric conversion system 11200 further includes a buffer memory unit 11206 for temporarily storing image data and an external interface unit (external I/F unit) 11209 for communicating with an external computer or the like. The photoelectric conversion system 11200 further includes a storage medium 11211 such as a semiconductor memory for storing and reading image data, and a storage medium control interface unit (storage medium control I/F unit) 11210 via which to store or read image data in/from the storage medium 11211. The storage medium 11211 may be disposed inside the photoelectric conversion system 11200 or may be detachable. Communication between the storage medium control I/F unit 11210 and the storage medium 11211 and/or communication with the external I/F unit 11209 may be performed wirelessly.

The photoelectric conversion system 11200 further includes an overall control/calculation unit 11208 that performs various calculations and controls the entire digital still camera, and a timing generation unit 11207 that outputs various timing signals to the photoelectric conversion apparatus 11204 and the signal processing unit 11205. The timing signal or the like may be input from the outside. In this case, the photoelectric conversion system 11200 may include at least the photoelectric conversion apparatus 11204 and the signal processing unit 11205 that processes an output signal provided from the photoelectric conversion apparatus 11204. The overall control/calculation unit 11208 and the timing generation unit 11207 may be configured to perform part or all of the control functions of the photoelectric conversion apparatus 11204.

The photoelectric conversion apparatus 11204 outputs an image signal to the signal processing unit 11205. The signal processing unit 11205 performs particular signal processing on the image signal output from the photoelectric conversion apparatus 11204, and outputs resultant image data. Furthermore, the signal processing unit 11205 generates an image using the image signal. The signal processing unit 11205 may perform a distance measurement calculation on the signal output from the photoelectric conversion apparatus 11204. The signal processing unit 11205 and the timing generation unit 11207 may be disposed on the photoelectric conversion apparatus. That is, the signal processing unit 11205 and the timing generation unit 11207 may be disposed on a substrate on which pixels are arranged, or may be disposed on another substrate. By forming an imaging system using the photoelectric conversion apparatus according to one of the embodiments described above, it is possible to realized an imaging system capable of acquiring a higher quality image.

### Fifth Embodiment

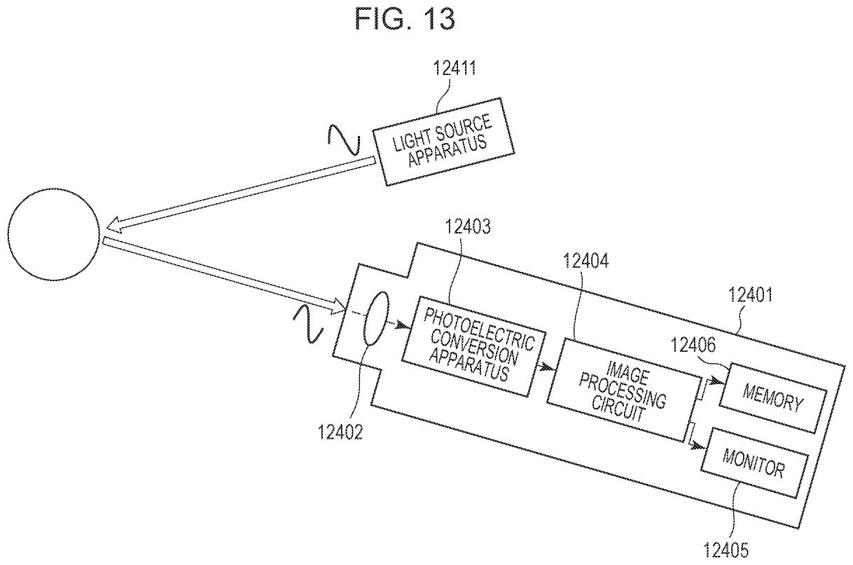

FIG. 13 is a block diagram showing an example of a configuration of a distance image sensor, which is an electronic device realized using the photoelectric conversion apparatus according to one of the embodiments described above.

As shown in FIG. 13, the distance image sensor 12401 includes an optical system 12407, a photoelectric conversion apparatus 12408, an image processing circuit 12404, a monitor 12405, and a memory 12406. The distance image sensor 12401 acquires a distance image indicating a distance to a subject by receiving light (modulated light or pulsed light) that is projected from a light source apparatus 12409 toward the subject and reflected by the surface of the subject.

The optical system 12407 includes one or a plurality of lenses and functions to conduct image light (incident light) from a subject to the photoelectric conversion apparatus 12408 so as to form an image on a light receiving surface (a sensor unit) of the photoelectric conversion apparatus 12408.

As the photoelectric conversion apparatus 12408, the photoelectric conversion apparatus according to one of the embodiments described above is used. A distance signal indicating a distance is obtained from a light reception signal output from the photoelectric conversion apparatus 12408, and the resultant distance signal is supplied to the image processing circuit 12404.

The image processing circuit 12404 performs image processing for constructing a distance image based on the distance signal supplied from the photoelectric conversion apparatus 12408. The distance image (image data) obtained by the image processing is supplied to the monitor 12405 and displayed thereon, or supplied to the memory 406 and stored (recorded) therein.

In the distance image sensor 12401 configured in the above-described manner, use of the photoelectric conversion apparatus with higher-quality pixels described above makes it possible to acquire, for example, a more accurate distance image.

### Sixth Embodiment

The techniques according to the present disclosure (the present techniques) can be applied to various products. For example, the techniques according to the present disclosure may be applied to endoscopic surgery systems.

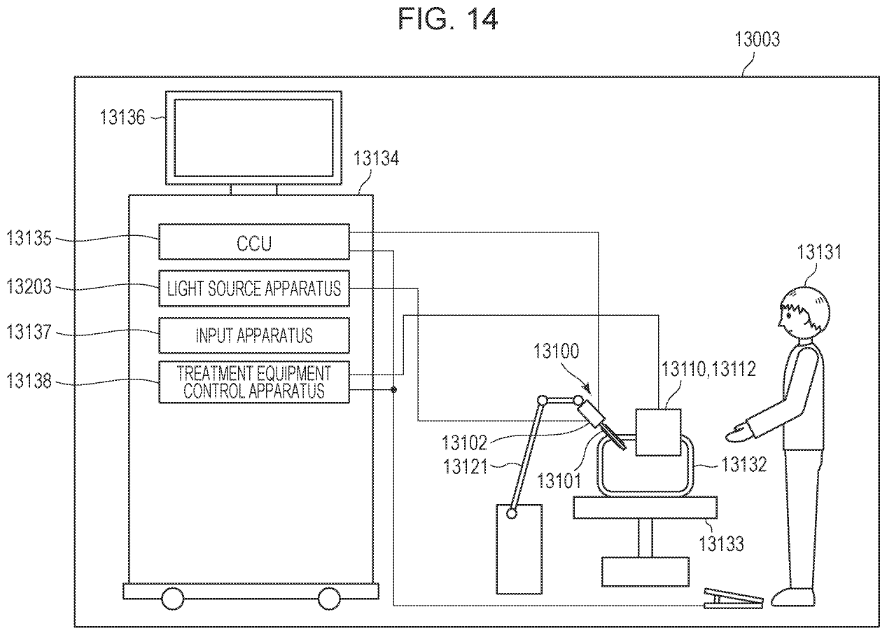

FIG. 14 is a schematic diagram showing an example of a configuration of an endoscopic surgery system to which the technique according to the present disclosure (the present technique) can be applied.

More specifically, FIG. 14 illustrates a manner in which a surgeon (doctor) 13131 performs surgery on a patient 13132 on a patient bed 13133 using an endoscopic surgery system 13003. As shown, the endoscopic surgery system 13003 includes an endoscope 13100, a surgical tool 13110, and a cart 13134 equipped with various apparatuses for endoscopic surgery.

The endoscope 13100 includes a lens barrel 13101 whose anterior part with a particular length is inserted in body cavity of the patient 13132, and a camera head 13102 connected to a base end of the lens barrel 13101. In the example shown in FIG. 14, the endoscope 13100 is configured as a so-called rigid endoscope having the rigid barrel 13101. However the endoscope 13100 may be configured as a so-called flexible endoscope having a flexible barrel.

An opening in which an objective lens is fitted is formed at the tip of the lens barrel 13101. A light source apparatus 13203 is connected to the endoscope 13100. Light generated by the light source apparatus 13203 is guided to the tip of the lens barrel by a light guide extending inside the lens barrel 13101. This light is emitted through the objective lens toward an observation target object in the body cavity of the patient 13132. The endoscope 13100 may be a forward-viewing endoscope, a forward-oblique viewing endoscope, or a side viewing endoscope.

An optical system and a photoelectric conversion apparatus are provided inside the camera head 13102, and reflected light (observation light) from the observation target object is focused on the photoelectric conversion apparatus by the optical system. The observation light is photoelectrically converted by the photoelectric conversion apparatus into an electric signal corresponding to the observation light. As a result, an image signal corresponding to the observation image is obtained. As the photoelectric conversion apparatus, the photoelectric conversion apparatus according to one of the embodiments described above may be used. The image signal is transmitted as RAW data to the camera control unit (CCU) 13135.

The CCU 13135 includes a CPU (Central Processing Unit), a GPU (Graphics Processing Unit), etc., and generally controls the operations of the endoscope 13100 and the display apparatus 13136. Furthermore, the CCU 13135 receives the image signal from the camera head 13102, and performs various image processing such as development processing (demosaic processing) on the image signal for displaying an image based on the image signal.

The display apparatus 13136 displays, under the control of the CCU 13135, the image based on the image signal subjected to the image processing by the CCU 13135.

The light source apparatus 13203 includes a light source such as an LED (Light Emitting Diode), and supplies irradiation light to the endoscope 13100 when an image of an operation part or the like is captured.

The input apparatus 13137 functions as an input interface to the endoscopic surgery system 13003. A user can input various information and instructions to the endoscopic surgery system 13003 via the input apparatus 13137.

The treatment equipment control apparatus 13138 controls driving of energy treatment equipment 13112 for cauterization or incision of a tissue, sealing of blood vessels, etc.

The light source apparatus 13203 for supplying irradiation light to the endoscope 13100 when an image of an operation part is captured may be realized using a white light source using an LED, a laser light source, or a combination thereof. In a case where the white light source is realized by a combination of RGB laser light sources, it is possible to accurately control the output intensity and output timing of each color (each wavelength), and thus the light source apparatus 13203 can adjust the white balance of the captured image. Furthermore, in this case, an image may be captured such that the laser light from each of the RGB laser light sources is supplied to the observation target object in a time-division manner, and the imaging device of the camera head 13102 is driven in synchronization with the light supplying timing so as to capture an image of each color in the time-division manner. In this method, a color image can be obtained without providing a color filter on the imaging device.

The light source apparatus 13203 may be controlled such that the intensity of the output light is changed at particular time intervals. By controlling the imaging device of the camera head 13102 to be driven in synchronization with the timing of the change in the light intensity to acquire images in a time-division manner and combining the images, it is possible to generate an image with a high dynamic range without having underexposure and overexposure.

The light source apparatus 13203 may be configured to be able to supply light in a particular wavelength band for special light observation. The special light observation is realized by using, for example, dependence of absorption of light by body tissues on wavelength of light absorption in body tissues. More specifically, a target tissue such as a blood vessel on the surface layer of a mucous membrane may be irradiated with light with a narrow band compared with normal irradiation light (that is, white light) thereby obtaining an image of the target issue with high contrast. Alternatively, the special light observation may be realized by fluorescence observation in which an image is obtained by fluorescence which occurs when a target is irradiated with excitation light. In the fluorescence observation, a body tissue is irradiated with excitation light, and fluorescence that occurs on the body tissue in response to the excitation by light is observed, or a reagent such as indocyanine green (ICG) is locally injected into the body tissue and the body tissue is irradiated with excitation light with a wavelength corresponding to the fluorescence wavelength of the reagent and a resultant fluorescence image is observed. As described above, the light source apparatus 13203 may be configured to be capable of supplying narrow band light and/or excitation light for the special light observation.

### Seventh Embodiment

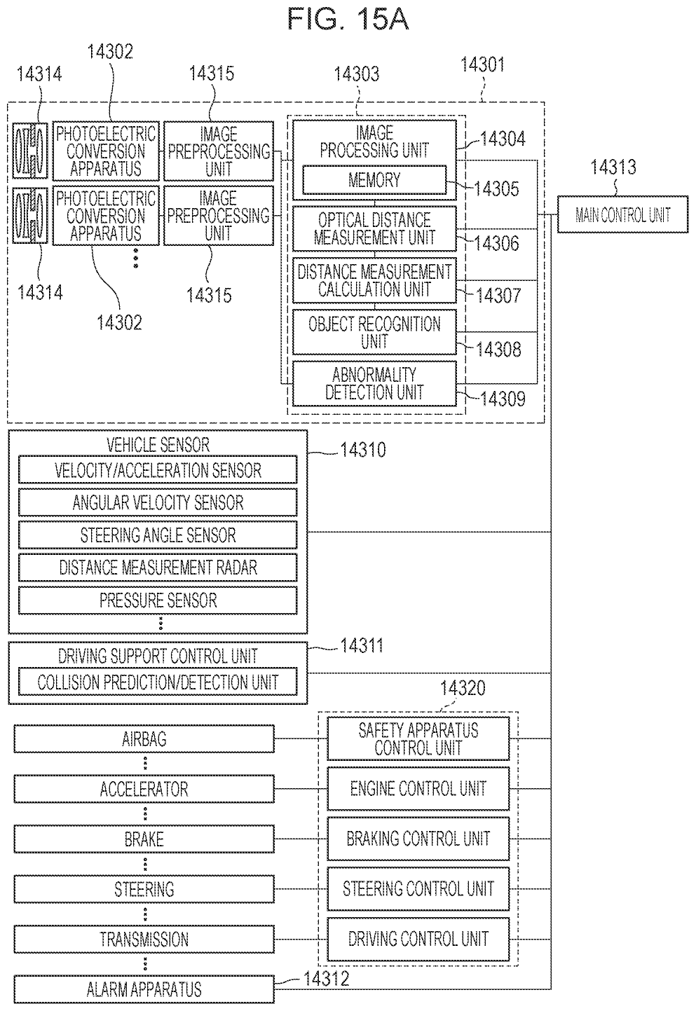

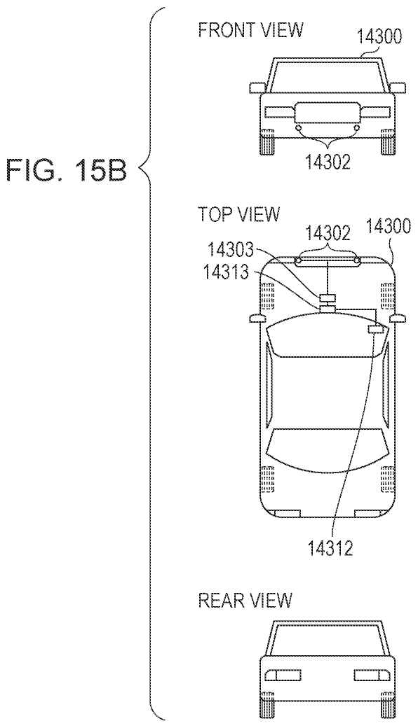

A photoelectric conversion system and a mobile body according to a seventh embodiment are described below with reference to FIGS. 15A and 15B. FIG. 15A is a schematic view showing an example of a configuration of a photoelectric conversion system according to the seventh embodiment and FIG. 15B shows an example of a configuration of a mobile body according to the seventh embodiment. In this embodiment, an in-vehicle camera is described as an example of the photoelectric conversion system.

More specifically, FIG. 15B shows an example of a vehicle system and FIG. 15A shows an example of a photoelectric conversion system for imaging which is disposed in the vehicle system. The photoelectric conversion system 14301 includes a photoelectric conversion apparatus 14302, an image preprocessing unit 14315, an integrated circuit 14303, and an optical system 14314. The optical system 14314 forms an optical image of a subject on the photoelectric conversion apparatus 14302. The photoelectric conversion apparatus 14302 converts the optical image of the subject formed by the optical system 14314 into an electric signal. The photoelectric conversion apparatus 14302 may be a photoelectric conversion apparatus according to one of the embodiments described above. The image preprocessing unit 14315 performs particular signal processing on the signal output from the photoelectric conversion apparatus 14302. The function of the image preprocessing unit 14315 may be incorporated in the photoelectric conversion apparatus 14302. The photoelectric conversion system 14301 includes at least two sets of the optical system 14314, the photoelectric conversion apparatus 14302, and the image preprocessing unit 14315, and is configured such that a signal output from the image preprocessing unit 14315 of each set is input to the integrated circuit 14303.

The integrated circuit 14303 is an integrated circuit designed for use in imaging system applications, and includes an image processing unit 14304 including a memory 14305, an optical distance measurement unit 14306, a distance measurement calculation unit 14307, an object recognition unit 14308, and an abnormality detection unit 14309. The image processing unit 14304 performs image processing such as development processing and/or defect correction processing on the output signal provided from the image preprocessing unit 14315. The memory 14305 temporarily stores the captured image and information indicating a position of a defect pixel. The optical distance measurement unit 14306 performs focusing of an image of a subject, and distance measurement processing. The distance measurement calculation unit 14307 calculates the distance from a plurality of image data acquired by the plurality of photoelectric conversion apparatuses 14302 thereby obtaining distance measurement information. The object recognition unit 14308 recognizes a subject such as a car, a road, a sign, or a person. When the abnormality detection unit 14309 detects an abnormality in the photoelectric conversion apparatus 14302, the abnormality detection unit 14309 notifies a main control unit 14313 of the abnormality.

The integrated circuit 14303 may be realized by hardware designed for dedicated use or by a software module, or may be realized by a combination thereof. Alternatively, the integrated circuit 14303 may be realized by an FPGA (Field Programmable Gate Array), an ASIC (Application Specific Integrated Circuit), or the like, or may be realized by a combination thereof.

The main control unit 14313 generally controls the operations of the photoelectric conversion system 14301, the vehicle sensor 14310, the control unit 14320, and the like. The main control unit 14313 may not be provided. In this case, a communication interface may be provided in each of the photoelectric conversion system 14301, the vehicle sensor 14310, and the control unit 14320, and a control signal may be transmitted among the photoelectric conversion system 14301, the vehicle sensor 14310, and the control unit 14320 via a communication network (according to, for example, CAN standard).

The integrated circuit 14303 has a function of transmitting a control signal or a setting value to the photoelectric conversion apparatus 14302 according to a control signal received from the main control unit 14313 or according to a control signal generated inside the integrated circuit 14303.

The photoelectric conversion system 14301 is connected to the vehicle sensor 14310, and can detect a running state in terms of the vehicle speed, yaw rate, steering angle and the like of the vehicle on which the photoelectric conversion system 14301 is disposed and also can detect a state of the environment outside the vehicle, the state of other vehicles/obstacles. The vehicle sensor 14310 also functions as a distance information acquisition unit for acquiring distance information indicating a distance to an object. The photoelectric conversion system 14301 is connected to a driving support control unit 1311 that provides various driving support such as automatic steering, automatic cruising, collision prevention, and/of the like. A collision prediction/detection function is also provided. In this function, a collision with another vehicle/object is predicted or an occurrence of a collision is detected based on a detection result provided by the photoelectric conversion system 14301 and/or the vehicle sensor 14310. When a collision is predicted, a control operation to avoid the collision is performed, and a safety apparatus is activated in the event of the collision.

The photoelectric conversion system 14301 is also connected to an alarm apparatus 14312 that issues an alarm to a driver based on the prediction/detection result by the collision prediction/detection unit. For example, in a case where the prediction/detection result by the collision prediction/detection unit indicates that a collision is going to occur with a high probability, the main control unit 14313 controls the vehicle to avoid the collision or reduce a damage by applying the brakes, releasing the accelerator, or suppressing the engine output.

The alarm apparatus 14312 warns the user by sounding an alarm, displaying alarm information on a display screen of a car navigation system or a meter panel, or vibrating a seat belt or a steering wheel.

In the present embodiment, an image around the vehicle is captured by the photoelectric conversion system 14301. More specifically, for example, an image of an environment in front of or behind the vehicle is captured. FIG. 15B shows an example of a manner of disposing the photoelectric conversion systems 14301 for a case where an image of an environment in front of the vehicle is captured by the photoelectric conversion system 14301.

The two photoelectric conversion apparatuses 14302 are disposed on the front of the vehicle 14300. More specifically, the center line of the external shape (for example, the width) of the vehicle 14300 extending in forward/backward running direction is taken as an axis of symmetry, and the two photoelectric conversion apparatuses 1302 are disposed line-symmetrically about the axis of symmetry. This configuration may be desirable for acquiring distance information indicating the distance between the vehicle 14300 and an imaging target object, and desirable for determining the possibility of collision.

The photoelectric conversion apparatuses 14302 may be disposed so as not to obstruct the field of view of the driver who is trying to view the situation outside the vehicle 14300 from the driver's seat. The alarm apparatus 14312 may be disposed such that the driver can be easily view the alarm apparatus 14312.

In the embodiment described above, by way of example, the control is performed to avoid a collision with another vehicle. However, the present embodiment can also be applied to a control to automatically drive following another vehicle, a control to automatically drive so as not to go out of a lane, and the like. Furthermore, the photoelectric conversion system 14301 can be applied not only to a vehicle but also to a mobile body (a mobile apparatus) such as a ship, an aircraft, an industrial robot, and/or the like. Furthermore, it can be applied not only to mobile bodies but also to a wide variety of devices that use object recognition processing, such as intelligent transportation systems (ITS).

The photoelectric conversion apparatus according to the present disclosure may be configured to be capable of acquiring various information such as distance information.

### Eighth Embodiment

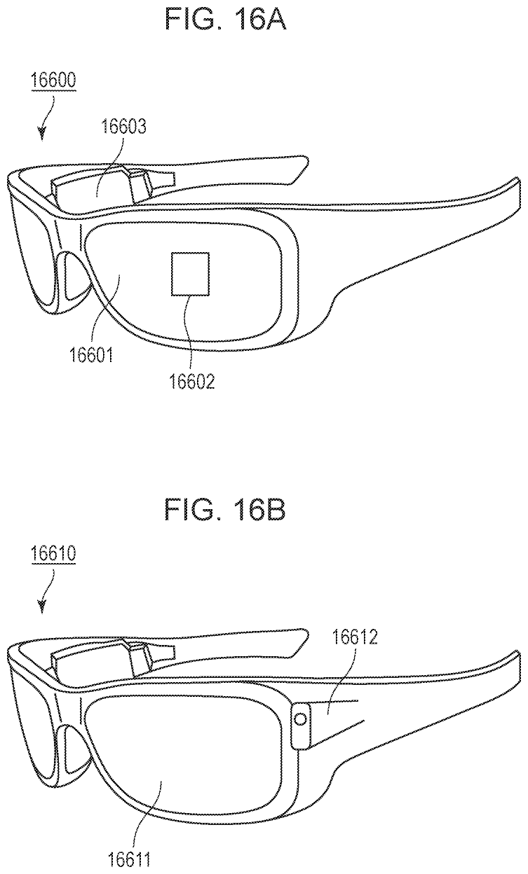

FIGS. 16A and 16B each illustrate, as one of examples of applications, eyeglasses 16600 (smart glasses). The eyeglasses 16600 have a photoelectric conversion apparatus 16602. The photoelectric conversion apparatus 16602 may be a photoelectric conversion apparatus according to one of the embodiments described above. A display apparatus including a light emitting device such as an OLED or an LED may be provided on a back surface side of a lens 16601. One or more photoelectric conversion apparatuses 16602 may be provided. When a plurality of photoelectric conversion apparatuses are used, types thereof may be the same or different. The position where the photoelectric conversion apparatuses 16602 is disposed is not limited to that shown in FIG. 16A.

The eyeglasses 16600 further include a control apparatus 16603. The control apparatus 16603 functions as a power source for supplying power to the photoelectric conversion apparatus 16602 and to the display apparatus described above. The control apparatus 16603 controls the operations of the photoelectric conversion apparatus 16602 and the display apparatus. The lens 16601 has an optical system for condensing light on the photoelectric conversion apparatus 16602.

FIG. 16B illustrates another example of eyeglasses 16610 (smart glasses).

The eyeglasses 16610 has a control apparatus 16612, wherein the control apparatus 16612 includes a display apparatus and a photoelectric conversion apparatus corresponding to the photoelectric conversion apparatus 16602. The lens 16611 has an optical system to project light generated by the display apparatus and the photoelectric conversion apparatus in the control apparatus 16612 thereby projecting an image on the lens 16611. The control apparatus 16612 functions as the power source for supplying electric power to the photoelectric conversion apparatus and the display apparatus, and functions to control the operations of the photoelectric conversion apparatus and the display apparatus. The control apparatus may include a line-of-sight detection unit that detects a line of sight of a user who wears the eyeglasses 16610. Infrared light may be used to detect the line of sight. An infrared light emitting unit emits infrared light toward an eyeball of the user who is gazing at the displayed image. An image of the eyeball can be obtained by detecting reflected light of the emitted infrared light from the eyeball by an imaging unit having a light receiving element. By providing a reducing unit for reducing light from the infrared light emitting unit to the display unit as seen in a plan view, the degradation in the image quality is reduced.

The user's line of sight to the displayed image is detected from the image of the eyeball captured using the infrared light. An arbitrary known method can be used in the line-of-sight detection using the captured image of the eyeball. For example, a line-of-sight detection method based on a Purkinje image using reflection of irradiation light on a cornea can be used.

More specifically, the line-of-sight detection process is performed based on a pupillary corneal reflex method. The line of sight of the user is detected by calculating a line-of-sight vector representing a direction (a rotation angle) of the eyeball based on the image of the pupil and the Purkinje image included in the captured image of the eyeball using the pupillary corneal reflex method.

The display apparatus according to the present embodiment may include a photoelectric conversion apparatus having a light receiving element, and may control the image displayed on the display apparatus based on the user's line-of-sight information provided from the photoelectric conversion apparatus.

More specifically, the display apparatus determines a first field-of-view area being watched by the user and a second field-of-view area other than the first field-of-view area based on the line-of-sight information. The first field-of-view area and the second field-of-view area may be determined by the control apparatus of the display apparatus, or may receive information indicating the first field-of-view area and the second field-of-view area determined by an external control apparatus. In the display area of the display apparatus, the display resolution of the first field-of-view area may be controlled to be higher than the display resolution of the second field-of-view area. That is, the resolution of the second field-of-view area may be lower than that of the first field-of-view area.

The display area may include a first display area and a second display area different from the first display area. The priorities for the first display area and the second display area may be determined based on the line-of-sight information. The first field-of-view area and the second field-of-view area may be determined by the control apparatus of the display apparatus, or may receive information indicating the first field-of-view area and the second field-of-view area determined by an external control apparatus. The resolution of the higher-priority area may be controlled to be higher than the resolution of the other area. That is, the resolution of the area having a relatively low priority may be controlled to be low.

Note that the determination of the first field-of-view area and the determination of the higher-priority area may be performed using A. The AI may be based on a model of estimating, from an image of an eyeball, the angle of the line of sight and the distance to a target object ahead of the line of sight, wherein the model is built by learning training data as to images of eyeballs and viewing directions of the eyeballs of the image. The AI program may be possessed by the display apparatus, the photoelectric conversion apparatus, or the external apparatus. In a case where the AI program is possessed by the external apparatus, it is transferred to the display apparatus via communication.

In a case where the displaying is controlled based on the visual detection, it is possible to preferably apply the technique to smart glasses further including a photoelectric conversion apparatus for capturing an image of the outside. Smart glasses can display captured external information in real time.

### Ninth Embodiment

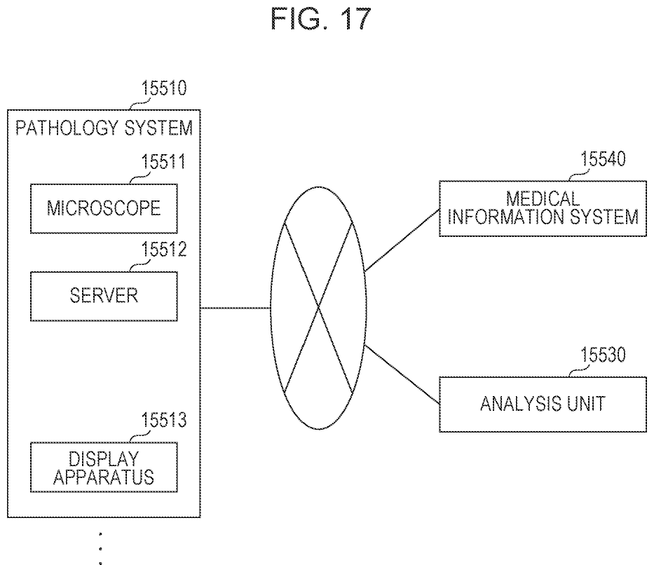

A system according to a ninth embodiment is described below with reference to FIG. 17. The system according to this twelfth embodiment can be applied to a pathological diagnosis system used by a doctor or the like to observe cells or tissues collected from a patient to diagnose a lesion, or to a diagnosis support system for supporting pathological diagnosis. The system according to the present embodiment may diagnose a lesion or assist the diagnosis based on an acquired image.

As shown in FIG. 17, the system according to the present embodiment includes one or more pathology systems 15510. The system may further include an analysis unit 15530 and a medical information system 15540.

Each of one or more pathology systems 15510 is a system mainly used by a pathologist and is installed, for example, in a laboratory or a hospital. The pathology systems 15510 may be installed in different hospitals, and they are connected to the analysis unit 15530 and the medical information system 15540 via various networks such as a wide area network, a local area network, etc.

Each pathology system 15510 includes a microscope 15511, a server 15512, and a display apparatus 15513.

The microscope 15511 has a function of an optical microscope, and is used to capture an image of an observation target object placed on a glass slide thereby acquiring a pathological image in the form of a digital image. The observation target object is, for example, a tissue or a cell collected from a patient. More specifically, for example, the observation target object may be a piece of meat of an organ, saliva, blood, or the like.

The server 15512 stores the pathological image acquired by the microscope 15511 in a storage unit (not shown). When the server 15512 receives a browsing request, the server 15512 may search for a pathological image stored in the storage unit (a memory or the like) and may display the retrieved pathological image on the display apparatus 15513. The server 15512 and the display apparatus 15513 may be connected via an apparatus that controls displaying.

In a case where an observation target object is a solid substance such as a piece of meat of an organ, the observation target object may be given, for example, in the form of a stained thin section. The thin section may be prepared, for example, by slicing a block piece cut out from a sample such as an organ into the thin section. When slicing is performed, the block piece may be fixed with paraffin or the like.

The microscope 15511 may include a low-resolution imaging unit for acquiring a low-resolution image and a high-resolution imaging unit for acquiring a high-resolution image. The low-resolution imaging unit and the high-resolution imaging unit may have different optical systems or may share the same optical system. When the same optical system is used, the resolution of the microscope 15511 may be changed depending on the imaging target object.

The observation target object is disposed in a glass slide or the like and placed on a stage located within the angle of view of the microscope 15511. The microscope 15511 first acquires an overall image within the angle of view using the low-resolution imaging unit, and identifies a particular area of the observation target object from the acquired overall image. Subsequently, the microscope 15511 divides the area where the observation target object exists into a plurality of divided areas each having a predetermined size, and sequentially captures images of the respective divided areas by the high-resolution imaging unit thereby acquiring high-resolution images of the respective divided areas. Switching of the divided area to be imaged may be realized by moving the stage or the imaging optical system or both the stage and the imaging optical system. Switching between divided areas may be performed such that there is an overlap between adjacent divided areas in order to prevent an occurrence of missing some part of a divided area due to unintended sliding of the glass slide. The overall image may include identification information for associating the overall image with the patient. This identification information may be given by, for example, a character string, a QR code (registered trademark), or the like.

The high-resolution image acquired by the microscope 15511 is input to the server 15512. The server 15512 may divide each high-resolution image into smaller-size partial images. When the partial images are generated in the manner described above, the server 15512 executes a composition process for generating one image by combining a predetermined number of adjacent partial images into a single image. This compositing process can be repeated until one final partial image is produced. By performing this processing, it is possible to obtain a group of partial images in a pyramid structure in which each layer is composed of one or more partial images. In this pyramid structure, a partial image of a layer has the same number of pixels as the number of pixels of a partial image of another different layer, but the resolution is different between layers. For example, when a total of 2×2 partial images are combined to generate one partial image in an upper layer, the resolution of the partial image in the upper layer is ½ times the resolution of the partial images in a lower layer used for the composition.

By constructing a partial image group in the pyramid structure, it is possible to switch the detail level of the observation target object displayed on the display apparatus depending on the layer to which the displayed tile images belong. For example, when a lowest-level partial image is used, a small area of the observation target object is displayed in detail, while when a higher-level partial image is used, a larger area of the observation target object is displayed in a coarse manner.

The generated partial image group in the pyramid structure can be stored in, for example, a memory. When the server 15512 receives a request for acquiring a partial image together with identification information from another apparatus device (for example, the analysis unit 15530), the server 15512 transmits the partial image corresponding to the identification information to this apparatus.

A partial image of a pathological image may be generated for each imaging condition such as a focal length, a staining condition, or the like. In a case where a partial image is generated for each imaging condition, partial images may be displayed such that, in addition to a specific pathological image, other pathological images which correspond to imaging conditions different from the imaging condition of the specific pathological image but correspond to the same region as that of the specific pathological image are displayed side by side. The specific imaging condition may be specified by a viewer. In a case where a plurality of imaging conditions are specified by the viewer, pathological images of the same area satisfying the respective imaging conditions may be displayed side by side.

The server 15512 may store a partial image group in the pyramid structure in a storage apparatus other than the server 15512, for example, a cloud server. Part or all of the partial image generation process described above may be executed by a cloud server or the like. By using partial images in the manner described above, a user can observe an observation target object as if the user is actually observing the observation target object while changing the observation magnification. That is, controlling the displaying provides a function of a virtual microscope. The virtual observation magnification actually corresponds to the resolution.

The medical information system 15540 is a so-called electronic medical record system. In this medical information system 15540, information is stored related to diagnosis such as patient identification information, patient disease information, test information and image information used in diagnosis, a diagnosis result, and a prescription. For example, a pathological image obtained by imaging an observation target object of a patient may be stored once in the server 15512 and may be displayed on the display apparatus 15514 later. A pathologist using the pathology system 15510 performs a pathological diagnosis based on the pathological image displayed on the display apparatus 15513. The result of the pathological diagnosis made by the pathologist is stored in the medical information system 15540.

The analysis unit 15530 is capable of analyzing the pathological image. A learning model built by machine learning may be used for the analysis. The analysis unit 15530 may derive a result of classification of a specific area, a result of an tissue identification, or the like as the analysis result. The analysis unit 15530 may further derive a result of cell identification, the number of cells, the position of cell, and luminance information, and scoring information for them. These pieces of information obtained by the analysis unit 15530 may be displayed as diagnostic support information on the display apparatus 15513 of the pathology system 15510.

The analysis unit 15530 may be realized by a server system including one or more servers (including a cloud server) and/or the like. The analysis unit 15530 may be incorporated in, for example, the server 15512 in the pathology system 15510. That is, various analysis on the pathological image may be performed within the pathology system 15510.

The photoelectric conversion apparatus according to the one of the embodiments described above can be suitably applied, in particular, to the microscope 15511 among various apparatuses. More specifically, the photoelectric conversion apparatus may be applied to the low-resolution imaging unit and/or the high-resolution imaging unit in the microscope 15511. This makes it possible to reduce the size of the low-resolution imaging unit and/or the high-resolution imaging unit, and, as a result, it becomes possible to reduce the size of the microscope 15511. As a result, it becomes easy to transport the microscope 15511, and thus it becomes easy to build the system or modify the system. Furthermore, by using the photoelectric conversion apparatus according to one of the embodiments described above, it becomes possible that part or all of the processes including acquiring an pathological image and other processes until analysis of the pathological image is completed can be executed on the fly by the microscope 15511, and thus it becomes possible to output accurate diagnostic support information quickly.

The techniques described above can be applied not only to the diagnosis support system but can be general applied to biological microscopes such as a confocal microscope, a fluorescence microscope, and a video microscope. The observation target object may be a biological sample such as cultured cells, a fertilized egg, or a sperm, a biomaterial such as a cell sheet or a three-dimensional cell tissue, or a living body such as a zebrafish or a mouse. In the observation, the observation target object is not limited to being placed on a glass slide, but can be stored in a well plate, a petri dish, or the like.

A moving image may be generated from still images of an observation target object acquired using a microscope. For example, a moving image may be generated from still images successively captured in a particular period, or an image sequence may be generated from still images captured at a particular interval. By generating a moving image from still images, it becomes possible to analyze, using machine learning, dynamic features of the observation target object such as beating or elongating of cancer cells, nerve cells, a myocardial tissue, a sperm, etc, movement such as migration, a division process of cultured cells or fertilized eggs, etc.

### OTHER EMBODIMENTS

The present disclosure has been described above with reference to various embodiments. However, the present disclosure is not limited to these embodiments, and various modifications and changes can possible. The embodiments may be mutually applicable. That is, a part of one embodiment may be replaced with a part of another embodiment, or a part of one embodiment may be added to another embodiment. Part of an embodiment may be deleted.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-016454, filed Feb. 4, 2021, which is hereby incorporated by reference herein in its entirety.

What is claimed is:

1. A photoelectric conversion apparatus comprising a first substrate having a pixel area in which a plurality of pixels are arranged, a second substrate disposed in a multilayer structure on the first substrate, and a heat dissipation structure,
the second substrate comprising a processing unit configured to execute a machine learning process on an image signal output from the pixel area,
the heat dissipation structure being disposed in a region adjacent to or in a region overlapping the processing unit when seen in a plan view, the processing unit,
the heat dissipation structure comprising one of following structures:
a structure formed on the second substrate, the structure being a semiconductor active region, polysilicon, a structure including a metal connection part, a TSV structure, or a cavity structure; or
a structure formed on the first substrate and electrically connected to the second substrate, the structure being a semiconductor active region, polysilicon, a structure including a metal connection part, a TSV structure, a cavity structure, or a heat dissipation structure attached to an area other than the pixel area.

2. The photoelectric conversion apparatus according to claim 1, wherein the structure including the metal connection part, the TSV structure, or the cavity structure connects the first substrate and the second substrate to each other.

3. The photoelectric conversion apparatus according to claim 1, wherein the heat dissipation structure is exposed on a surface of the first substrate.

4. The photoelectric conversion apparatus according to claim 1, wherein the heat dissipation structure is not in contact with a surface of the first substrate.

5. The photoelectric conversion apparatus according to claim 1, wherein
the photoelectric conversion apparatus has a first plane of the first substrate and a second plane opposing the first plane, and
the heat dissipation structure is exposed on the surface of the second plane.

6. A photoelectric conversion apparatus comprising a first substrate having a pixel area in which a plurality of pixels are arranged, a second substrate disposed in a multilayer structure on the first substrate, and a heat dissipation structure,
the second substrate having a third plane and a fourth plane opposing the third plane, the third plane being bonded to the first substrate,
the heat dissipation structure including a TSV structure or a cavity structure exposed on a surface of the photoelectric conversion apparatus on a side of the fourth plane.

7. The photoelectric conversion apparatus according to claim 6, wherein the heat dissipation structure is not in contact with a surface of the first substrate.

8. The photoelectric conversion apparatus according to claim 1, further comprising a third substrate bonded to the second substrate.

9. The photoelectric conversion apparatus according to claim 8, wherein the third substrate has a heat dissipation structure.

10. The photoelectric conversion apparatus according to claim 1, wherein the heat dissipation structure is MEMS.

11. A photoelectric conversion apparatus comprising a first substrate, a second substrate disposed in a multilayer structure on the first substrate, and a third substrate bonded to the second substrate,
the first substrate having a pixel area in which a plurality of pixels are arranged,
the third substrate being a heat dissipation structure using a MEMS structure.

12. The photoelectric conversion apparatus according to claim 10, wherein the heat dissipation structure has a microfluidic structure.

13. The photoelectric conversion apparatus according to claim 12, wherein the second substrate comprising a processing unit configured to execute a machine learning process on an image signal output from the pixel area.

14. The photoelectric conversion apparatus according to claim 1, wherein the heat dissipation structure is disposed in a mesh form.

15. A photoelectric conversion system, comprising:
the photoelectric conversion apparatus according to claim 1, and
a signal processing unit configured to generate an image using a signal output by the photoelectric conversion apparatus.

16. A mobile body comprising:
the photoelectric conversion apparatus according to claim 1, and
a control unit configured to control a movement of the mobile body using a signal output by the photoelectric conversion apparatus.

17. A semiconductor substrate having a pixel area in which a plurality of pixels are arranged, the semiconductor substrate comprising:
a processing unit configured to execute a machine learning process on an image signal output from the pixel area, and
a heat dissipation structure, the heat dissipation structure comprising a structure disposed in a region adjacent to or in a region overlapping the processing unit when seen in a plan view, the structure being a semiconductor active region, polysilicon, a structure including a metal connection part, a TSV structure, or a cavity structure.
